(19) United States
(12) Patent Application Publication
(10) Pub. No.: US 2025/0038148 A1
(43) Pub. Date: Jan. 30, 2025

(54) SEMICONDUCTOR PACKAGE STRUCTURE AND METHOD OF FORMING SAME

(71) Applicant: Taiwan Semiconductor Manufacturing Co., Ltd., Hsinchu (TW)

(72) Inventors: Wei-Chih Chen, Taipei City (TW); Jhih-Yu Wang, New Taipei City (TW); Po-Han Wang, Hsinchu (TW); Yu-Hsiang Hu, Hsinchu (TW); Hung-Jui Kuo, Hsinchu (TW)

(21) Appl. No.: 18/403,418

(22) Filed: Jan. 3, 2024

Related U.S. Application Data
(60) Provisional application No. 63/515,392, filed on Jul. 25, 2023.

(51) Int. Cl. H01L 25/065; H01L 21/48; H01L 21/56; H01L 23/00; H01L 23/31; H01L 23/48; H01L 23/522; H01L 25/00; H10B 80/00

(52) U.S. Cl. CPC H01L 25/0652; H01L 21/4853; H01L 21/4857; H01L 21/56; H01L 23/3121; H01L 23/481; H01L 23/5226; H01L 24/16; H01L 25/50; H10B 80/00; H01L 24/32; H01L 24/73; H01L 2224/16227; H01L 2224/32225; H01L 2224/73204

(57) ABSTRACT

A method includes forming a metal post over a first redistribution structure; attaching a first device die to the first redistribution structure, the first device die comprising a through via embedded in a semiconductor substrate; encapsulating the metal post and the first device die in an encapsulant, a first top surface of the encapsulant being level with a second top surface of the semiconductor substrate; recessing the second top surface to expose the through via; forming a dielectric isolation layer around the through via; forming a dielectric layer over the dielectric isolation layer; etching the dielectric layer to form a first opening and a second opening in the dielectric layer; forming a first metal via in the first opening and a second metal via in the second opening; and forming a second redistribution structure over the dielectric layer.

### PRIORITY CLAIM AND CROSS-REFERENCE

This application claims the benefit of the following provisionally filed U.S. Patent application: Application No. 63/515,392, filed on Jul. 25, 2023, and entitled “InFO_3D TSV Die for TSV Reveal,” which application is hereby incorporated herein by reference.

### BACKGROUND

The packages of integrated circuits are becoming increasing complex, with more device dies integrated in the same package to achieve more functions. For example, a plurality of device dies such as processors and memory cubes may be bonded and integrated together. The package can include device dies formed using different technologies and have different functions, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17 illustrate cross-sectional views of intermediate stages in the formation of a semiconductor package, in accordance with some embodiments.

FIGS. 18-23 illustrate cross-sectional views of intermediate stages in the formation of a semiconductor package, in accordance with some embodiments.

FIGS. 24 and 25 illustrate cross-sectional views of various semiconductor packages, in accordance with some embodiments.

FIGS. 26-34 illustrate cross-sectional views of intermediate stages in the formation of a semiconductor package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package and the method of forming the same are provided. In accordance with some embodiments of the present disclosure, the formation of the semiconductor package includes forming a metal via electrically coupling to a through substrate via (TSV), which penetrates through a semiconductor substrate of a device die. A back-side of the semiconductor substrate is thinned (which may or may not expose the TSV), and a sacrificial carrier is attached to the thinned semiconductor substrate of the device die to form a composite die. The composite die may be attached to a wafer (e.g., a redistribution structure) and encapsulated in an encapsulant, which is then planarized to remove the sacrificial carrier and to reveal the semiconductor substrate. The semiconductor substrate is recessed below top surfaces of the TSV, and a dielectric isolation layer is deposited over the semiconductor substrate and planarized to be level with the TSV. A buffer structure is then formed over the dielectric isolation layer, which protects the device die during formation of the buffer structure. The buffer structure includes a metal via embedded in a dielectric layer.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

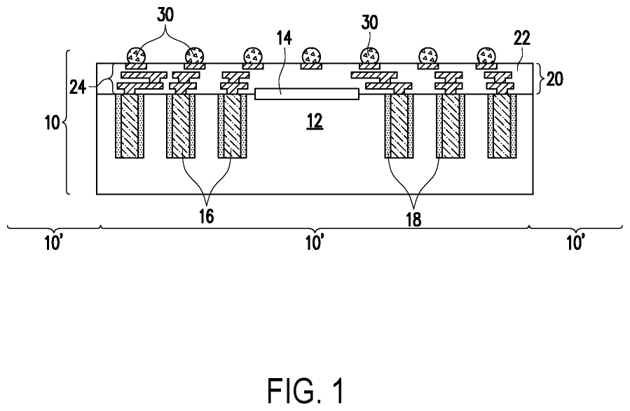

FIGS. 1 through 17 illustrate cross-sectional views of intermediate stages in the formation of a semiconductor package in accordance with some embodiments of the present disclosure. FIG. 1 illustrates the formation of a device wafer in accordance with some embodiments. Wafer 10 includes a plurality of device dies 10′ therein. Device wafer 10 includes substrate 12. In accordance with some embodiments, substrate 12 is a semiconductor substrate, which may include or be a crystalline silicon substrate, while it may also comprise or be formed of other semiconductor materials such as silicon germanium, carbon-doped silicon, or the like. In accordance with some embodiments, device dies 10′ include active circuits 14, which include active devices such as transistors (not shown) formed along the top surface of semiconductor substrate 12.

Through vias (also referred to as Through Substrate Vias (TSVs)) 16 may be formed to extend into substrate 12 in accordance with some embodiments. TSVs 16 are also sometimes referred to as through silicon vias when formed in a silicon substrate. Each of TSVs 16 may be encircled by dielectric isolation liners 18, which are formed of a dielectric material such as silicon oxide, silicon nitride, or the like. The isolation liners 18 electrically and physically isolate the respective TSVs 16 from semiconductor substrate 12. TSVs 16 and the isolation liners 18 extend from a top surface of semiconductor substrate 12 to an intermediate level between the top surface and the bottom surface of semiconductor substrate 12. In accordance with some embodiments, the top surfaces of TSVs 16 are level with the top surface of semiconductor substrate 12. In accordance with alternative embodiments, TSVs 16 extend into one of dielectric layers 22, and extend from a top surface of the corresponding dielectric layer 22 down into semiconductor substrate 12.

Interconnect structure 20 is formed over semiconductor substrate 12. Interconnect structure 20 may include a plurality of dielectrics layers 22 and conductive features 24 in the dielectric layers 22. The conductive features 24 may electrically connect to TSVs 16 and active circuits 14.

In accordance with some embodiments, dielectric layers 22 are formed of silicon oxide, silicon nitride, silicon carbide, silicon oxynitride, combinations thereof, and/or multi-layers thereof. Dielectric layers 22 may comprise one or more Inter-Metal-Dielectric (IMD) layers formed of low-k dielectric materials having low k values, which may be, for example, lower than about 3.0, or in the range between about 2.5 and about 3.0. Dielectric layers 22 may also include passivation layers over the low-k dielectric layers, which passivation layers may be formed of non-low-k dielectric materials such as oxide, nitride, combinations thereof, and/or compositions thereof. Some of the upper ones of dielectric layers 22 may also comprise or may be formed of polymer(s) such as polybenzoxazole (PBO), polyimide, benzocyclobutene (BCB) or the like.

The conductive features 24 may include metal lines and vias, which may be formed in the low-k dielectric layers. The metal lines and vias may be formed using damascene processes in accordance with some embodiments. There may be some metal pads (such as aluminum copper pads) over the low-k dielectric layers and in the passivation layers and/or the non-low-k dielectric layers.

Electrical connectors 30 are formed over interconnect structure 20 along the top surface of device dies 10′. In accordance with some embodiments, electrical connectors 30 comprise solder regions, metal pillars, metal pads, metal bumps (sometimes referred to as micro-bumps), or the like. The material of electrical connectors 30 may include non-solder materials, which may be formed of or comprise copper, nickel, aluminum, gold, multi-layers thereof, alloys thereof, or the like. Electrical connectors 30 may be electrically connected to active circuits 14.

Throughout the description, the side of semiconductor substrate 12 having the active circuits 14 and interconnect structure 20 is referred to as a front side (or active side) of semiconductor substrate 12, and the opposite side is referred to as a back side (or inactive side) of semiconductor substrate 12. Also, the front side of semiconductor substrate 12 is referred to as the front side (or active side) of wafer 10 (e.g., device dies 10′), and the backside of semiconductor substrate 12 is also referred to as the backside (or inactive side) of device die 10′ (e.g., wafer 10).

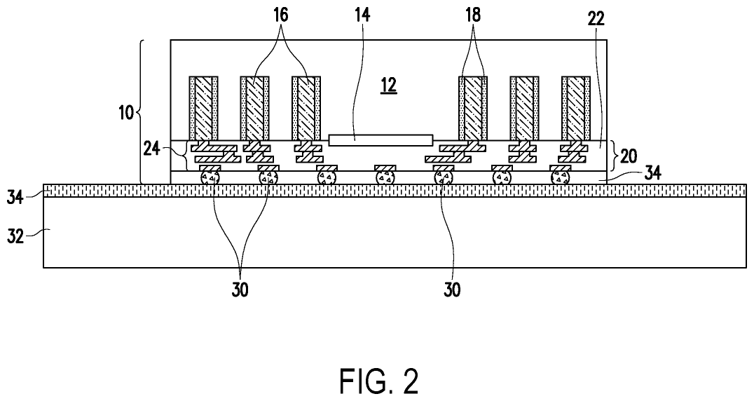

Referring to FIG. 2, wafer 10 is attached to carrier 32 and release film 34. Carrier 32 may be a glass carrier, a silicon wafer, an organic carrier, or the like. Carrier 32 may have a round top-view shape in accordance with some embodiments. Release film 34 may be a glue and may be formed of a polymer-based material and/or an epoxy-based thermal-release material (such as a Light-To-Heat-Conversion (LTHC) material), which is capable of being decomposed under radiation such as a laser beam, so that carrier 32 may be de-bonded from the overlying structure. In accordance with some embodiments of the present disclosure, release film 34 is applied on carrier 32 through coating.

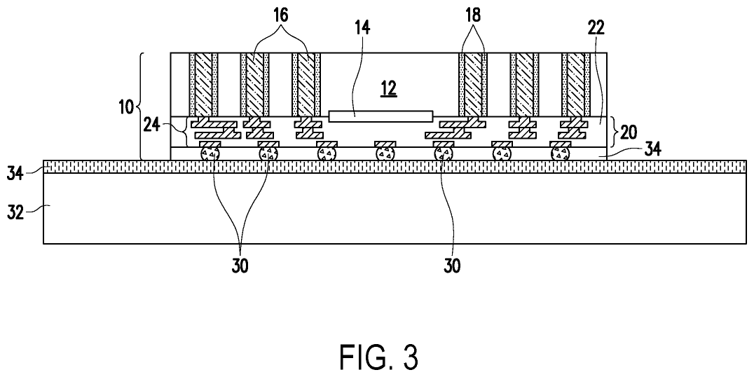

Referring to FIG. 3, a backside thinning process is performed on the backside of device wafer 10, wherein semiconductor substrate 12 is thinned. The backside grinding process may be performed through a Chemical Mechanical Polish (CMP) process or a mechanical polishing process. In some embodiments, following the backside thinning process, TSVs 16 are exposed.

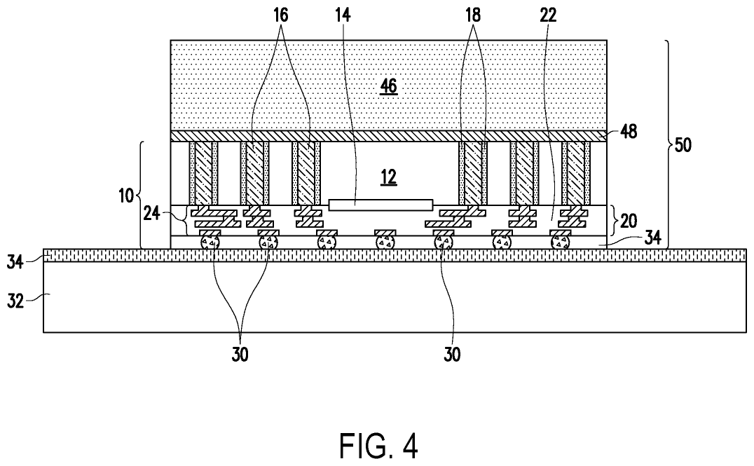

FIG. 4 illustrates the attachment of sacrificial carrier 46 to wafer 10. The attachment may be performed using adhesion film 48. Wafer 10, which was thinned in preceding processes, may be too thin for subsequent processes, and may suffer from breakage and/or warpage. For example, the thickness of wafer 10 may be in the range between about 30 μm and about 50 μm. Sacrificial carrier 46 may thus provide mechanical support. In accordance with some embodiments, sacrificial carrier 46 is formed of or comprises a silicon wafer, a glass wafer, or the like. Sacrificial carrier 46 may also be an inorganic or an organic carrier. The thickness of sacrificial carrier 46 is great enough for providing support to wafer 10 and the device dies 10′ in subsequent processes, and not overly thick since it will be removed through grinding or CMP. In accordance with some embodiments, the thickness of sacrificial carrier 46 may be in the range between about 500 μm and about 700 μm. Throughout the description, the structure including wafer 10 and the sacrificial carrier 46 may be collectively referred to as composite wafer 50.

In accordance with some embodiments, sacrificial carrier 46 is thinned in a backside grinding process to a suitable thickness, so it is adequate to provide support to wafer 10, but is not too thick. In accordance with alternative embodiments, no thinning of sacrificial carrier 46 is performed.

The composite wafer 50 is then de-bonded from carrier 32, for example, by projecting UV light or a laser beam, which penetrates through carrier 32 and is projected on release film 34. Release film 34 is decomposed under the heat of the UV light or the laser beam. The composite wafer 50 may then be separated from carrier 32.

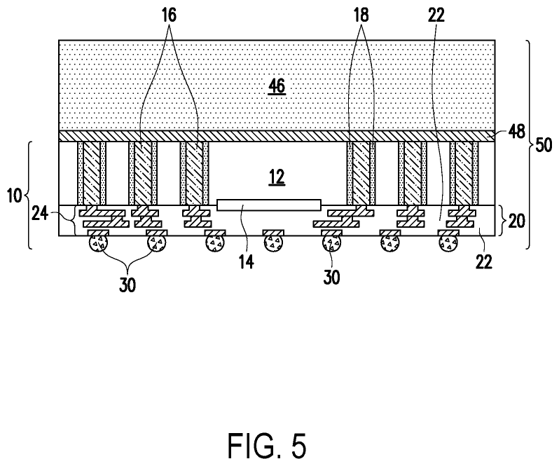

Referring to FIG. 5, in a subsequent process, composite wafer 50 is singulated, for example, sawed into a plurality of discrete dies 50′, which are referred to as composite dies 50′. In the sawing process, composite wafer 50 may be fixed on a dicing tape (not shown), which is further fixed on a frame (not shown). Each of composite dies 50′ includes carrier die 46′, which is a blank die cut from carrier 46, and device die 10′, which is a part of wafer 10.

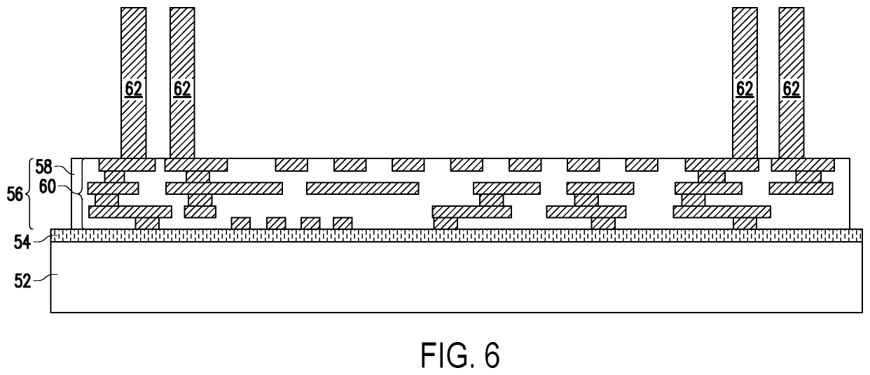

FIGS. 6 through 17 illustrate packaging of discrete dies 10′ in accordance with some embodiments. Referring to FIG. 6, carrier 52 is provided, with release film 54 being coated on carrier 52. Carrier 52 may be a glass carrier, a silicon wafer, an organic carrier, or the like. Release film 54 may be formed of a polymer-based material and/or an epoxy-based thermal-release material, such as a LTHC material. There may be a buffer dielectric layer (not shown) such as a PBO layer formed on release film 54.

Redistribution structure 56, which includes a plurality of dielectric layers 58 and a plurality of RDLs 60, is formed over release film 54. Redistribution structure 56 may be alternatively referred to as interposer 56. In accordance with some embodiments, redistribution structure 56 is pre-formed, and the pre-formed redistribution structure 56 is placed on release film 54. Redistribution structure 56 may be an organic interposer comprising organic dielectric layers 58 and redistribution lines 60.

In accordance with alternative embodiments, redistribution structure 56 is formed on carrier 52 layer-by-layer. For example, the formation of RDLs 60 may include forming a dielectric layer 58, and forming openings in dielectric layer 58 through a patterning process. A metal seed layer (not specifically illustrated) is deposited, which includes some portions over, and some other portions extending into dielectric layer 58. Dielectric layers 58 may be formed of or comprise an organic material such as PBO, polyimide, BCB, or the like, or inorganic materials such as silicon oxide, silicon nitride, or the like. A patterned mask (not specifically illustrated) such as a photoresist is then formed over the metal seed layer, followed by a metal plating process to deposit a metallic material on the exposed metal seed layer. The patterned mask and the portions of the metal seed layer covered by the patterned mask are then removed, leaving a layer of RDLs 6o.

In accordance with some embodiments, the metal seed layer includes a titanium layer and a copper layer over the titanium layer. The metal seed layer may be formed using, for example, Physical Vapor Deposition (PVD) or a like process. The plated material may include copper, aluminum, cobalt, nickel, gold, silver, tungsten, or alloys thereof. The plating may be performed using, for example, an electrochemical plating process. The dielectric layers 58 and RDLs 60 are formed layer-by-layer, and collectively forming redistribution structure 56.

Metal posts 62 are then formed. In accordance with some embodiments, the formation process includes depositing a metal seed layer, forming and patterning a plating mask such as a photoresist, plating a metallic material in the plating mask, removing the plating mask, and removing the portions of the metal seed layer previously covered by the plating mask. The plated metallic material and the remaining portions of the metal seed layer are collectively referred to as metal posts 62.

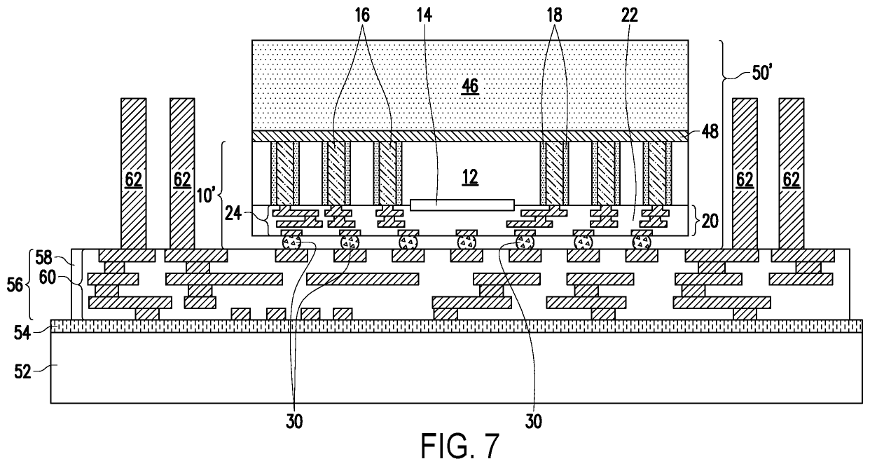

Next as shown in FIG. 7, composite die 50′ is bonded to redistribution structure 56, for example, through electrical connectors 30, which are bonded to the metal pads, metal pillars, or the like in redistribution structure 56. Although one composite die 50′ is illustrated, there may be a plurality of composite dies 50′ bonded over the same carrier 52. The front side of device die 10′ faces redistribution structure 56.

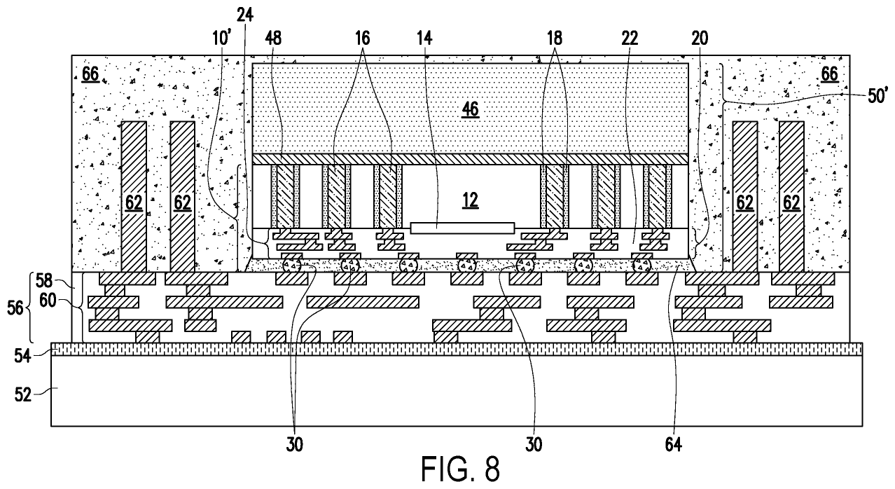

Referring to FIG. 8, underfill 64 is dispensed into the gap between device die 10′ and redistribution structure 56. Next, composite die 50′ and metal posts 62 are encapsulated in encapsulant 66. Encapsulant 66 fills the gaps between neighboring metal posts 62 and the gaps between metal posts 62 and composite die 50′. Encapsulant 66 may include a molding compound, a molding underfill, an epoxy, and/or a resin. The top surface of encapsulant 66 may be higher than the top surface of sacrificial die 46′. When formed of molding compound, encapsulant 66 may include a base material, which may be a polymer, a resin, an epoxy, or the like, and filler particles in the base material. The filler particles may be dielectric particles of SiO₂, Al₂O₃, silica, or the like, and may have spherical shapes. Also, the spherical filler particles may have a plurality of different diameters.

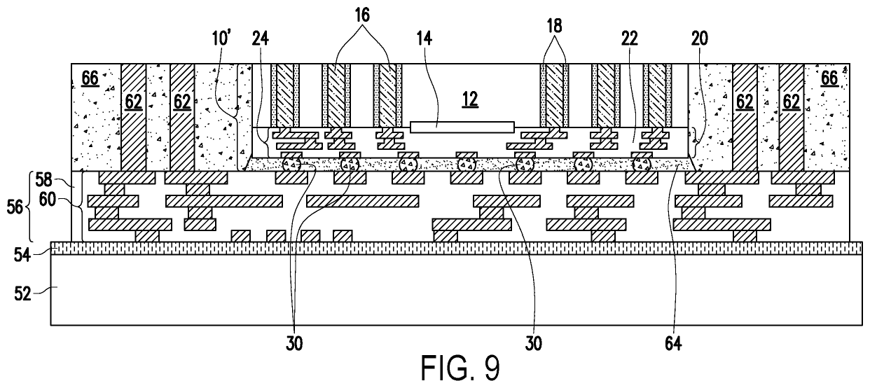

Referring to FIG. 9, a planarization process such as a CMP process or a mechanical grinding process is performed to thin encapsulant 66 and composite die 50′, until metal posts 62 are exposed and sacrificial die 46′ is removed. Metal posts 62 are alternatively referred to as through-vias 62 hereinafter since they penetrate through encapsulant 66.

In the planarization process, sacrificial die 46′ is removed, and adhesion film 48 is also removed, hence exposing the underlying metal vias 40. Sacrificial wafer 46 (see FIG. 4) is used to support the sawing of the thin wafer 10 (see FIG. 5) when the thin wafer 10 is de-bonded from carrier 32, and provides mechanical support during the bonding of thin die 10′ to redistribution structure 56. In some embodiments (not specifically illustrated), sacrificial die 46′ may be removed after forming underfill 64 and before forming encapsulant 66. As such, the planarization process removes portions of encapsulant 66 over the back side of device die 10′ as well as any remaining amounts of adhesion film 48. Following the planarization process, semiconductor substrate 12 and TSVs 16 (e.g., device die 10′) are exposed and level with metal posts 62 and encapsulant 66 within process variations.

Note that benefits have been achieved by having already performed the backside thinning process of semiconductor substrate 12 (see FIG. 3). In particular, thinning processes performed on device dies 10′ after attachment to redistribution structure 56 may be more expensive, more time consuming, and/or riskier for damaging device dies 10′ due to small pitches and delicateness of TSVs 16 in comparison with the larger sizes of metal posts 62. However, previously performing the backside thinning process on wafer 10 allowed for the process to be less costly, more efficient, and higher yield because the structure and its surface were more consistent as compared to the structure of FIGS. 8 and 9.

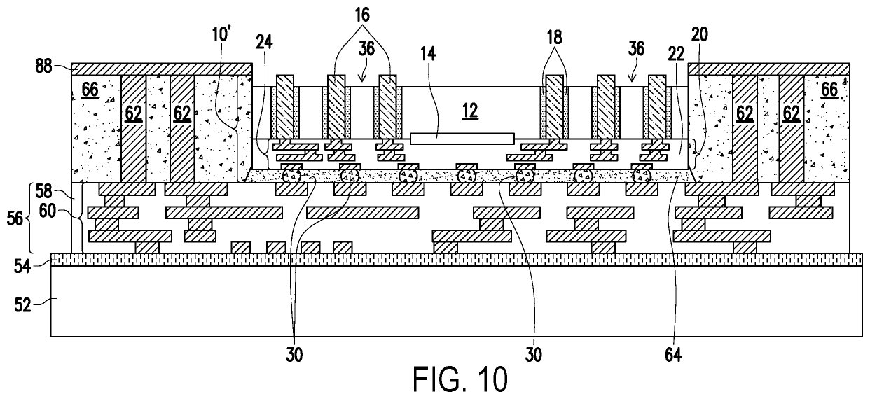

Referring to FIG. 10, a photoresist 88 is deposited and patterned to be disposed over a top surface of the encapsulant 66. Semiconductor substrate 12 is then recessed through an etch-back process. Accordingly, the top portions of TSVs 16 protrude higher than the top surface (e.g., the back side surface) of semiconductor substrate 12. In the recessing process, the dielectric isolation liners 18 may be recessed, for example, have top ends level with the top surface of semiconductor substrate 12, and hence the sidewalls of the protruding top portions of TSVs 16 are exposed. The space higher than the back side surface of semiconductor substrate 12 and lower than the top ends of TSVs 16 are referred to as recesses 36. In some embodiments (not specifically illustrated), the dielectric isolation liners 18 are not recessed (or are partially recessed), and hence the protruding top portions of TSVs 16 are encircled by the corresponding top portions of dielectric isolation liners 18. The recessing depth of semiconductor substrate 12 may be in the range between about 0.5 μm and about 3 μm.

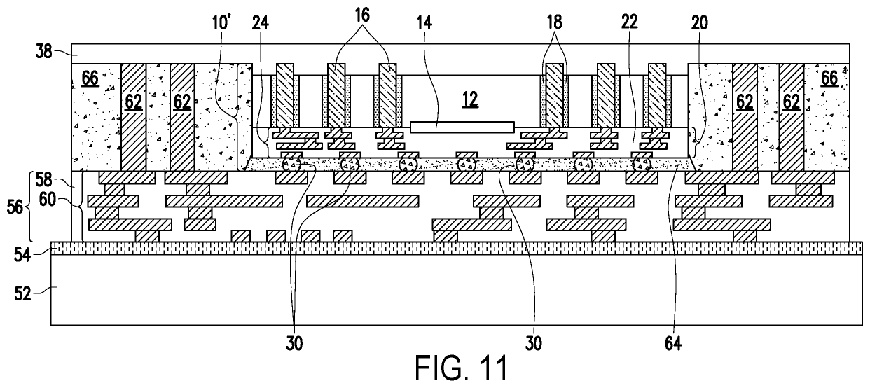

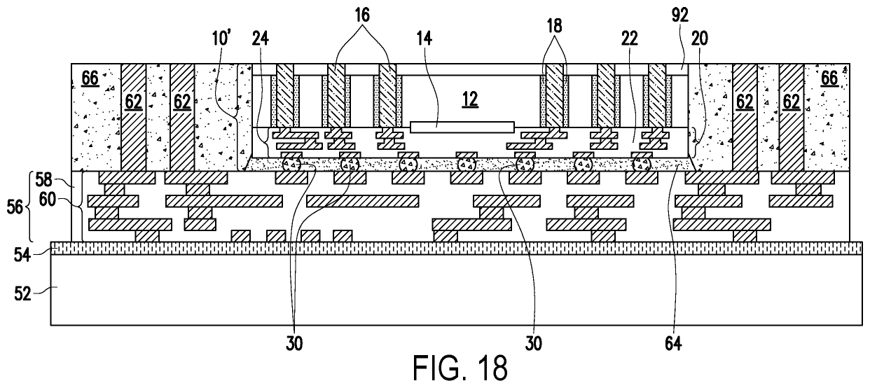

Referring to FIG. 11, photoresist 88 is removed and recesses 36 are filled with dielectric isolation layer 38. Photoresist 88 may be removed by any suitable process, such as a stripping or ashing process. In accordance with some embodiments, dielectric isolation layer 38 may comprise an organic dielectric material such as an epoxy, PBO, polyimide, BCB, or the like. The formation process may comprise a conformal or non-conformal deposition process, which may be performed by spin coating, Chemical Vapor Deposition (CVD), lamination, or the like. In accordance with some embodiments, dielectric isolation layer 38 is formed of or comprises an inorganic dielectric material (see FIGS. 18-23 and 25) such as silicon nitride, silicon oxynitride, silicon oxycarbonitride, silicon oxide, silicon carbide, silicon oxycarbide, or the like, or combinations thereof. The formation process may comprise a conformal or non-conformal deposition process, which may be performed using Atomic Layer Deposition (ALD), CVD, Plasma-Enhanced Chemical Vapor Deposition (PECVD), or the like. Dielectric isolation layer 38 may also be deposited using a low-temperature deposition process. For example, when dielectric isolation layer 38 comprises silicon nitride, it may be deposited at a temperature in a range between about 300° C. and about 500° C. Dielectric isolation layer 38 may have a thickness in the range between about 0.5 μm and about 3 μm.

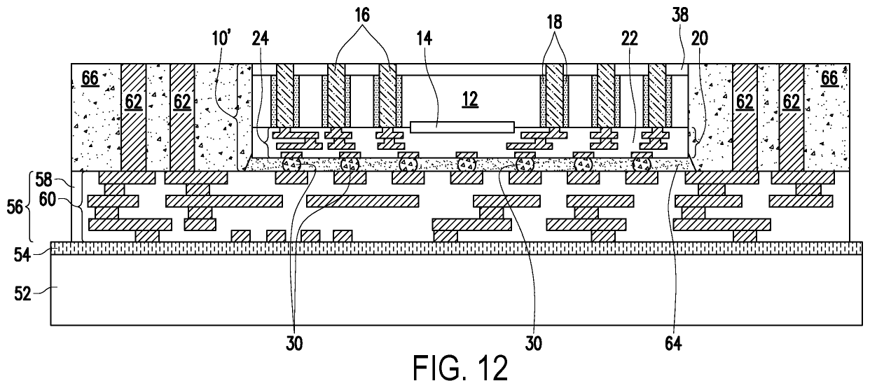

Referring to FIG. 12, after depositing dielectric isolation layer 38, a planarization process is performed to remove the portions of dielectric isolation layer 38 higher than the top ends of TSVs 16. As a result, the top surface of dielectric isolation layer 38 is coplanar with the top ends of TSVs 16. The top portions of TSVs 16 are also encircled by dielectric isolation layer 38. In embodiments (not specifically illustrated) in which dielectric isolation liners 18 are not recessed when semiconductor substrate 12 is recessed, dielectric isolation layer 38 is separated from the top portions of TSVs 16 by the corresponding dielectric isolation liners 18. In accordance with embodiments in which isolation liners 18 are recessed when semiconductor substrate 12 is recessed (as illustrated) or partially recessed, dielectric isolation layer 38 is in physical contact with the top portions (e.g., upper sidewalls) of TSVs 16.

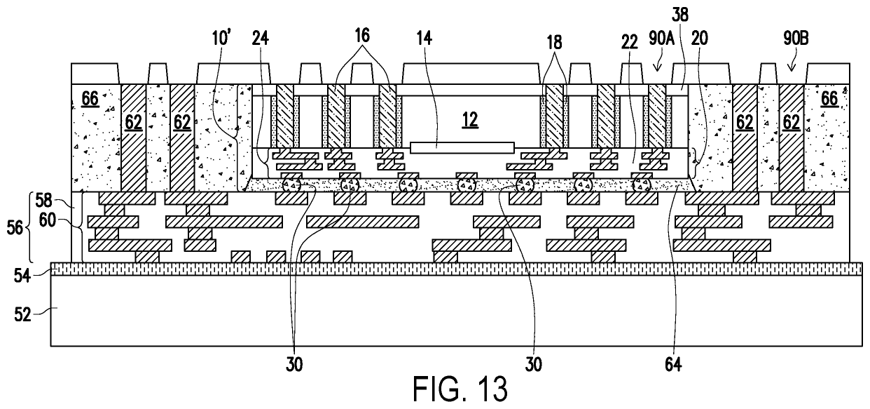

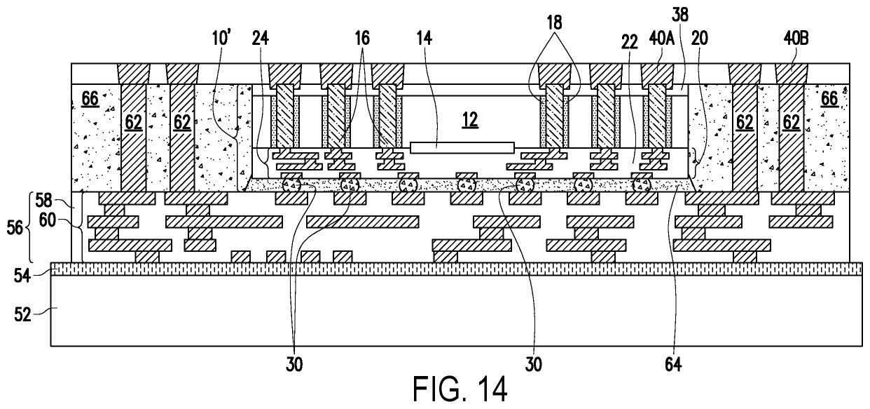

FIGS. 13 and 14 illustrate forming a buffer structure comprising metal vias 40 embedded in dielectric layer 42. For example, metal vias 40 may be formed over device die 10′ and metal posts 62 through a damascene process, in accordance with various embodiments. Referring to FIG. 13, the formation process may include depositing dielectric layer 42, and then performing a patterning process to form openings 90 in dielectric layer 42. In accordance with some embodiments, dielectric layer 42 may comprise an organic dielectric material such as PBO, polyimide, BCB, or the like. Alternatively, dielectric layer 42 may comprise an inorganic material such as silicon oxide, silicon nitride, silicon carbide, silicon oxynitride, silicon oxycarbide, silicon oxycarbonitride, or the like, or combinations thereof (see FIGS. 18-23).

Openings 90 reveal the underlying TSVs 16 and metal posts 62, and openings 90 may also reveal dielectric isolation layer 38. In particular, openings 90A reveal underlying TSVs 16, and openings 90B reveal underlying metal posts 62. It should be appreciated that dielectric isolation liners 18 may be or may not be revealed by openings 90A, depending on whether they are recessed (and by how much) during the formation of recesses 36 as described above. In accordance with various embodiments, openings 90 have widths that are greater than widths of TSVs 16 such that openings 90 in dielectric layer 42 reveal portions of underlying dielectric isolation layer 38. Etchants used to form openings 90 may be selected so that dielectric isolation layer 38 remains substantially unetched. In some embodiments, a thickness of dielectric layer 42 (and depths of openings 90) are in the range of between 10 μm and 30 μm.

Referring to FIG. 14, after forming and patterning dielectric layer 42, a conductive layer(s) is deposited in openings 90 in dielectric layer 42 to form metal vias 40. In accordance with some embodiments, each of metal vias 40 may include a conformal diffusion barrier layer (also referred to as an adhesion layer), which may include titanium, titanium nitride, tantalum, tantalum nitride, or other alternatives. An inner conductive material is deposited over the adhesion layer, and may include a metallic material such as copper, a copper alloy, silver, gold, tungsten, aluminum, or the like. A planarization process such as a CMP process may be performed to level the surface of the conductive materials and to remove the conductive materials from a top surface of dielectric layer 42, leaving metal vias 40 embedded in dielectric layer 42.

Metal vias 40A are formed in openings 90A over TSVs 16, and metal vias 40B are formed in openings 90B over metal posts 62. As illustrated, the weight of the conductive materials of metal vias 40A cause directly underlying portions of dielectric isolation layer 38 (e.g., comprising an organic polymer material) to compress. As a result, metal vias 40A may physically contact sidewalls of top portions of TSVs 16. For example, dielectric isolation layer 38 may compress an amount ranging from 0.3 μm to 0.5 μm, such as being about 0.5 μm. Heights of metal vias 40A may be equal to the thickness of dielectric layer 42 plus the compression depth (e.g., about 0.5 m).

It should also be noted that the weight of the conductive materials of metal vias 40B may be substantially supported by directly underlying portions of encapsulant 62. As a result, heights of metal vias 40B may be equal to the thickness of dielectric layer 42. For example, heights of metal vias 40A may be greater than heights of metal vias 40B.

In accordance with some embodiments, the widths of metal vias 40 may be greater than or equal to the widths of TSVs 16. For example, the widths of metal vias 40 may range from 8 μm to 12 μm (such as about 10 μm), and the widths of TSVs 16 may range from 4 μm to 5 μm (such as about 4.5 μm). Metal vias 40 may also be in physical contact with the top ends of dielectric isolation liners 18, or may be spaced apart from the top ends of dielectric isolation liners 18 by dielectric isolation liners 38, depending on whether dielectric isolation liners 18 have been recessed or not.

Note that benefits have been achieved by forming the buffer structure after attaching device die 10′ to redistribution structure 56. In particular, this feature reduces the amount of time that carrier 32 is attached to wafer 10 (e.g., pre-singulated device die 10′). Because carrier 32 is attached by release film 34 (e.g., glue), the reduced amount of time ensures that less water is absorbed by release film 34, which would otherwise cause defects to wafer 10. For example, defects that are prevented or reduced may include bulges or warpage in wafer 10, which also lowers costs and improves yield.

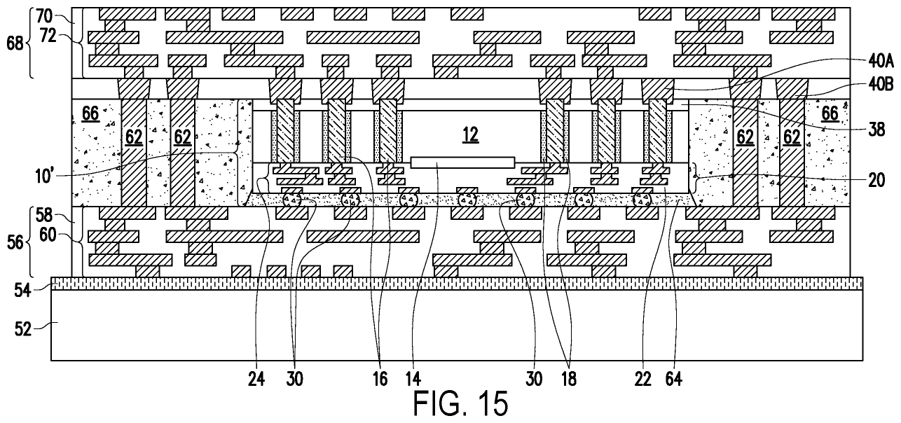

FIG. 15 illustrates the formation of redistribution structure 68, which includes dielectric layers 70 and RDLs 72 in dielectric layers 70. The materials, the structures, and the formation process may be similar to or the same as that of redistribution structure 56, and are not repeated herein. As illustrated, redistribution structure 68 may be electrically connected to device die 10′ through metal vias 40A and to redistribution structure 56 through metal vias 40B and metal posts 62.

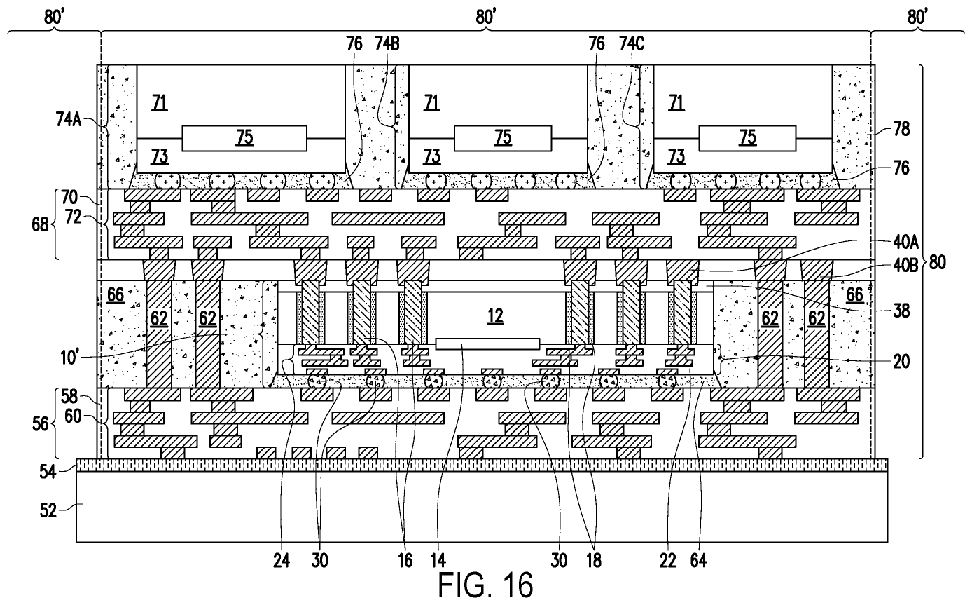

FIG. 16 illustrates the bonding of package components 74 to redistribution structure 68 in accordance with some embodiments. Since the front sides of package components 74 face the back side of device die 10′, the bonding is referred to as face-to-back bonding. Package components 74 may include device dies, multi-die stacks, packages, or the like. In accordance with some embodiments, package components 74 are device dies, and include semiconductor substrates 71 and interconnect structures 73. Integrated circuit devices 75 are formed on the front sides of semiconductor substrates 71. Underfill 76 is dispensed into the gaps between the package components 74 and the underlying redistribution structure 68. Encapsulant 78 is then dispensed, cured, and planarized. The structure over release film 54 is referred to as reconstructed wafer 80.

Although three package components 74 are illustrated, any number of package components 74 may be attached to redistribution structure 68. For example, each package component 74 may be a logic die (e.g., central processing unit (CPU), graphics processing unit (GPU), system-on-a-chip (SoC) die, application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof. In accordance with some embodiments, package component 74A is a memory die (e.g., DRAM die) and package components 74B and 74C are logic dies (e.g., SoC dies).

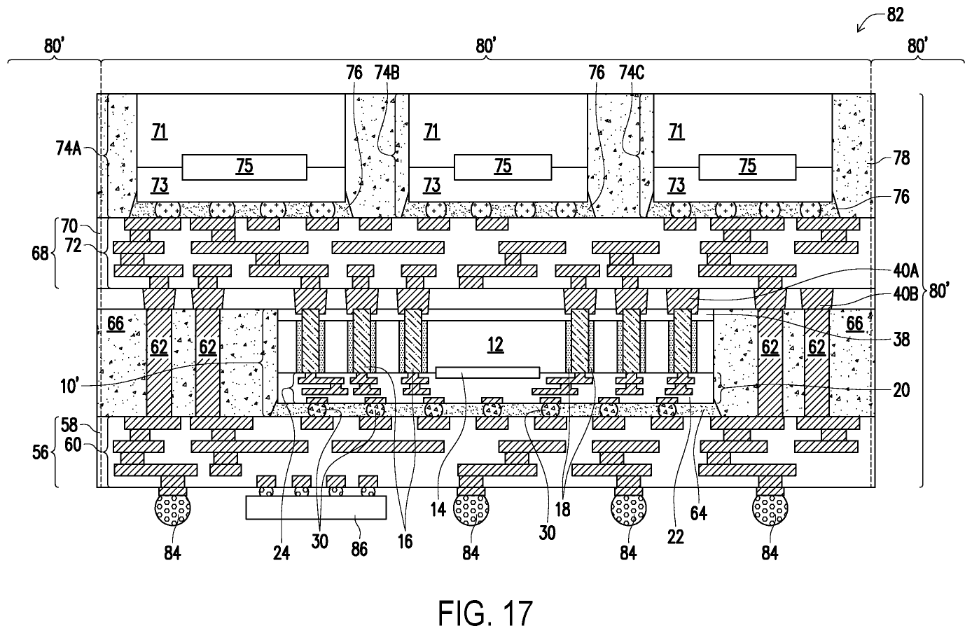

Referring to FIG. 17, reconstructed wafer 80 is de-bonded from carrier 52. Reconstructed wafer 80 is singulated to form a plurality of packages 80′. In addition, more processes may be performed on package 80′ (either before or after the singulation of the reconstructed wafer 80) to form package 82. For example, external connectors or electrical connectors 84 (e.g., solder regions) may be formed on redistribution structure 56, and discrete dies such as Independent Passive Devices (IPD) dies 86 may be bonded to redistribution structure 56. Package 82′ may thus undergo testing and/or be incorporated into an electronic device.

FIGS. 18 through 23 illustrate cross-sectional views of intermediate stages in the formation of a package in accordance with alternative embodiments of the present disclosure. These embodiments are similar to the embodiments as shown in FIGS. 1 through 17, except that the dielectric isolation layer (herein dielectric isolation layer 92) comprises a different material that does not compress during formation of the overlying metal vias (herein metal vias 94). The resulting metal vias 94 formed over TSVs 16 will have different shapes (e.g., heights) as compared to metal vias 40A described above in connection with FIGS. 13 and 14. In addition, metal vias 94 will have substantially the same shapes (e.g., heights) as metal vias 94 directly overlying metal posts 62 and as metal vias 40B described above in connection with FIGS. 13 and 14. Unless specified otherwise, the materials, the structures, and the formation processes of the components in these embodiments are essentially the same as the like components denoted by like reference numerals in the preceding embodiments. The details regarding the materials, the structures, and the formation processes of the components shown in FIGS. 18 through 23 may thus be found in the discussion of the preceding embodiments.

Referring to FIG. 18, subsequent processing steps are performed on a structure such as that of FIG. 10, which includes metal posts 62 and device die 10′ being disposed over and electrically connected to redistribution structure 56 and being encapsulated by encapsulant 66. In addition, semiconductor substrate 12 of device die 10′ has been recessed in order for TSVs 16 to protrude above semiconductor substrate 12. Similarly as the embodiments above, dielectric isolation liners 18 are illustrated as being recessed with semiconductor substrate 12, however, dielectric isolation liners 18 may remain non-recessed or partially recessed. The formation process, the structures, and materials of device dies 10′, redistribution structure 56, metal posts 62, and encapsulant 66 may be found referring to the discussion of FIGS. 1-17, and are not repeated herein.

Similarly as described above, dielectric isolation layer 92 is deposited over the structure (see FIG. 11) and planarized to remove dielectric isolation layer 92 from top surfaces of encapsulant 66 and metal posts 62 (see FIG. 12). In accordance with various embodiments, dielectric isolation layer 92 comprises an inorganic material. For example, dielectric isolation layer 38 may be silicon nitride, silicon oxynitride, silicon oxycarbonitride, silicon oxide, silicon carbide, silicon oxycarbide, or the like, or combinations thereof. The formation process may be the same as described above, such as being a conformal or non-conformal deposition process, which may be performed using ALD, CVD, PECVD, the like, or using a suitable method.

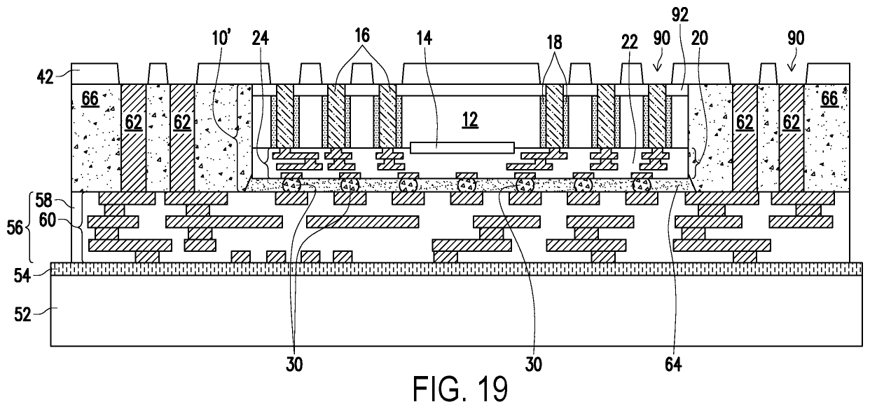

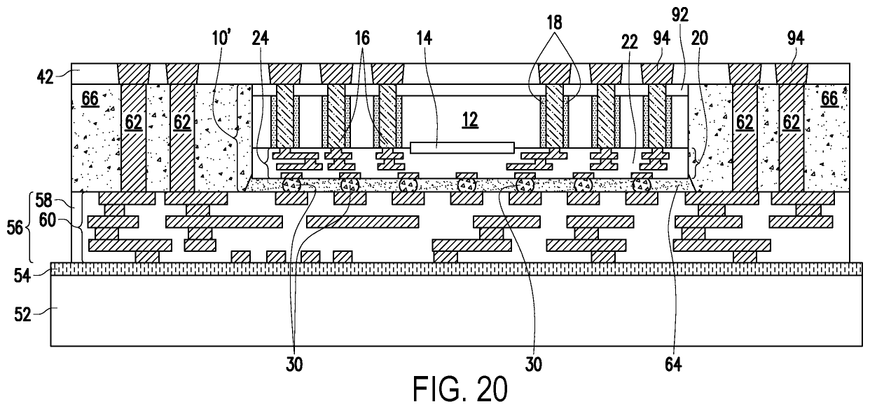

FIGS. 19 and 20 illustrate forming a buffer structure comprising metal vias 94 embedded in dielectric layer 42. For example, metal vias 94 may be formed over device die 10′ and metal posts 62 through a damascene process, in accordance with various embodiments. Referring to FIG. 19, the formation process may include depositing dielectric layer 42 over dielectric isolation layer 92, and then a patterning process is performed to form openings 90 in dielectric layer 42. Openings 90 reveal the underlying TSVs 16 and metal posts 62, and openings 90 may also reveal dielectric isolation layer 38 and dielectric isolation liners 18. In particular, dielectric isolation liners 18 may be or may not be revealed, depending on whether they are recessed (and by how much) during the formation of recesses 36 to expose TSVs 16 as described above in connection with FIG. 10.

As discussed above, dielectric layer 42 may comprise an inorganic material such as silicon oxide, silicon nitride, silicon carbide, silicon oxynitride, silicon oxycarbide, silicon oxycarbonitride, or the like, or combinations thereof. Alternatively, dielectric layer 42 may comprise an organic dielectric material such as PBO, polyimide, BCB, or the like. In accordance with some embodiments, the thickness of dielectric layer 42 (and depths of openings 90) may be in the range of between about 10 μm and about 30 μm. Dielectric layer 42 may be formed similarly as described above with respect to previous embodiments.

Referring to FIG. 20, after forming and patterning dielectric layer 42, a conductive layer(s) is deposited in openings 90 in dielectric layer 42 to form metal vias 94. In accordance with some embodiments, each of metal vias 94 may include a conformal diffusion barrier layer (also referred to as an adhesion layer), which may include titanium, titanium nitride, tantalum, tantalum nitride, or other alternatives. An inner conductive material is deposited over the adhesion layer, and may include a metallic material such as copper, a copper alloy, silver, gold, tungsten, aluminum, or the like. A planarization process such as a CMP process may be performed to level the surface of the conductive materials and to remove the conductive materials from a top surface of dielectric layer 42, leaving metal vias 94 embedded in dielectric layer 42.

Metal vias 94 are formed in openings 90 over both TSVs 16 and metal posts 62. As illustrated, the weight of the conductive materials of metal vias 94 may be substantially supported by directly underlying portions of dielectric isolation layer 92 (e.g., comprising an inorganic polymer material) and encapsulant 62. As a result, heights of metal vias 94 may be equal to the thickness of dielectric layer 42.

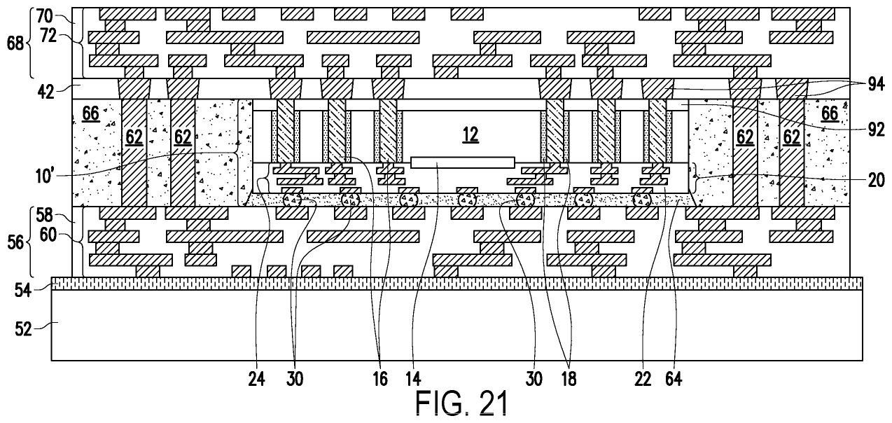

FIG. 21 illustrates the formation of redistribution structure 68, which includes dielectric layers 70 and RDLs 72 in dielectric layers 70. The materials, the structures, and the formation process may be similar to or the same as that of redistribution structure 56, and are not repeated herein. As illustrated, redistribution structure 68 may be electrically connected to device die 10′ through metal vias 94 and to redistribution structure 56 through metal vias 94 and metal posts 62.

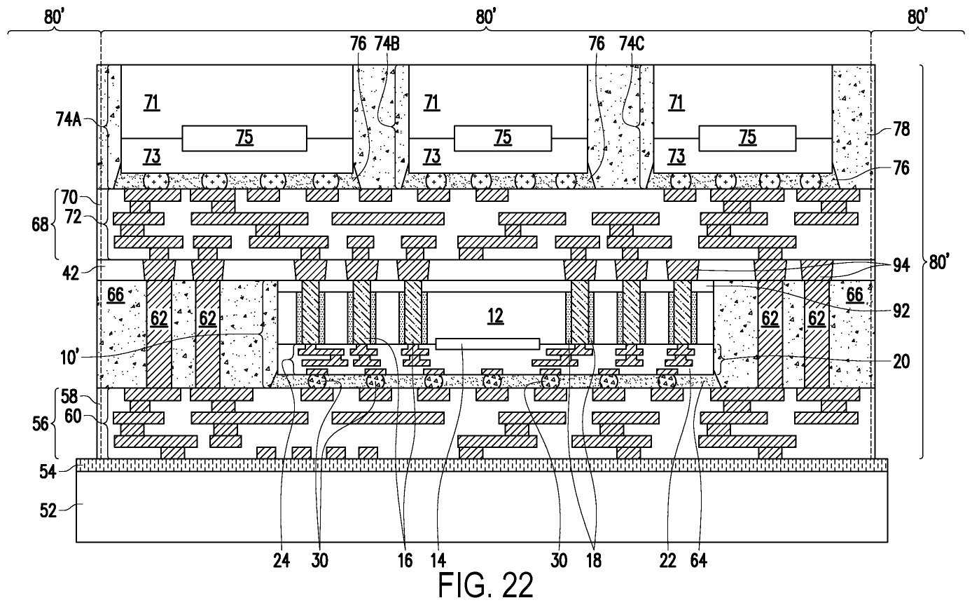

FIG. 22 illustrates the bonding of package components 74 to redistribution structure 68 in accordance with some embodiments. Since the front sides of package components 74 face the back side of device dies 10′, the bonding is referred to as face-to-back bonding. Package components 74 may include device dies, multi-die stacks, packages, or the like. In accordance with some embodiments, package components 74 are device dies, and include semiconductor substrates 71 and interconnect structures 73. Integrated circuit devices 75 are formed on the front sides of semiconductor substrates 71. Underfill 76 is dispensed into the gaps between package components 74 and the underlying redistribution structure 68. Encapsulant 78 is then dispensed, cured, and planarized. The structure over release film 54 is referred to as reconstructed wafer 80. Next, reconstructed wafer 80 is de-bonded from carrier 52. Reconstructed wafer 80 is singulated to form a plurality of packages 80′.

Although three package components 74 are illustrated, any number of package components 74 may be attached to redistribution structure 68. For example, each package component 74 may be a logic die (e.g., CPU, GPU, SoC die, AP, microcontroller, etc.), a memory die (e.g., DRAM die, SRAM die, etc.), a power management die (e.g., PMIC die), an RF die, an interface die, a sensor die, a MEMS die, a signal processing die (e.g., DSP die), a front-end die (e.g., AFE dies), the like, or combinations thereof. In accordance with some embodiments, package component 74A is a memory die (e.g., DRAM die) and package components 74B and 74C are logic dies (e.g., SoC dies).

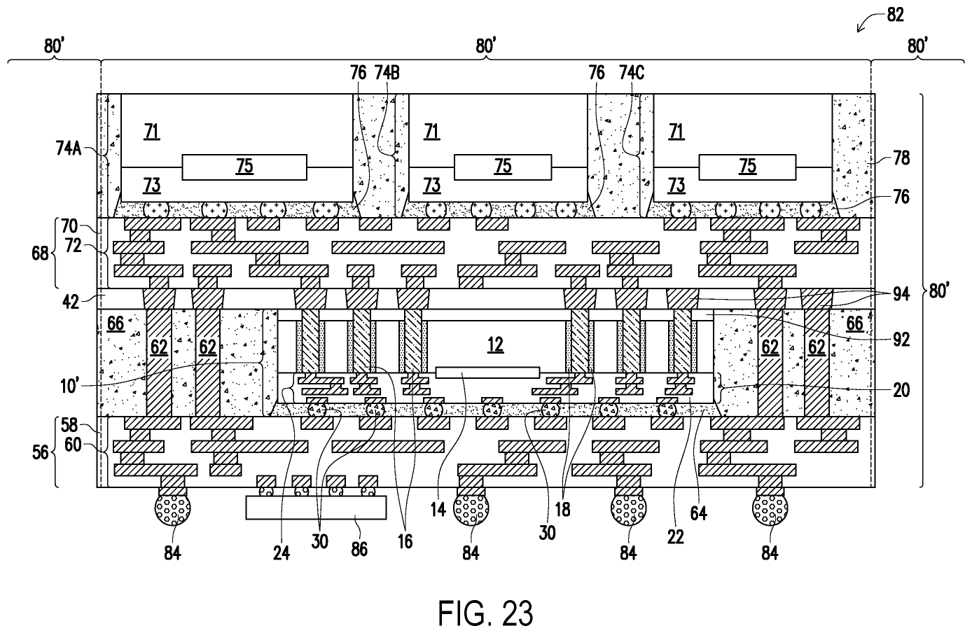

Referring to FIG. 23, reconstructed wafer 80 is de-bonded from carrier 52. Reconstructed wafer 80 is singulated to form a plurality of packages 80′. In addition, more processes may be performed on package 80′ (either before or after the singulation of the reconstructed wafer 80) to form package 82. For example, electrical connectors 84 (e.g., solder regions) may be formed on redistribution structure 56, and discrete dies such as IPD dies 86 may be bonded to redistribution structure 56. Package 82′ may thus undergo testing and/or be incorporated into an electronic device.

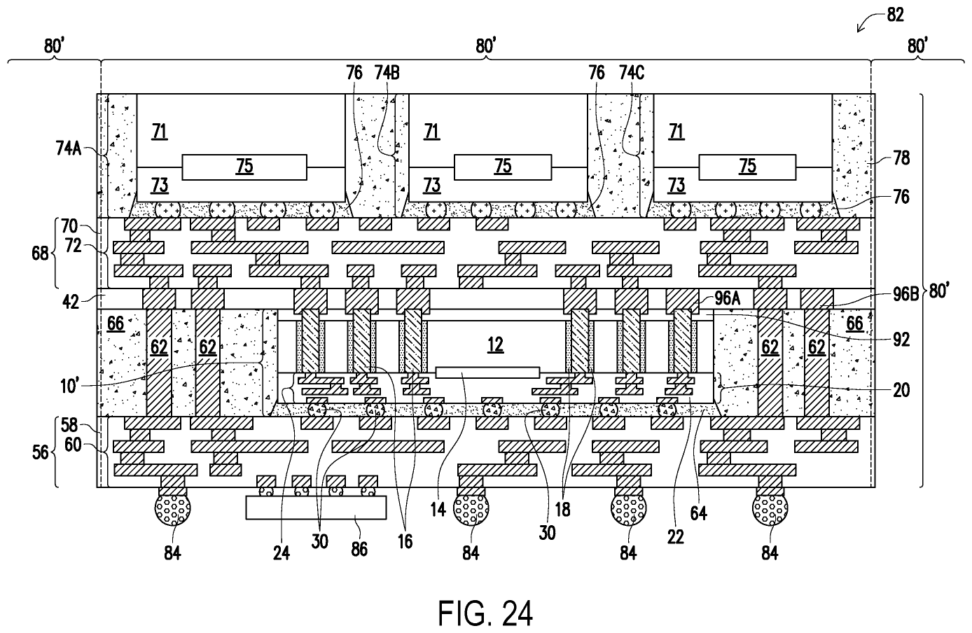

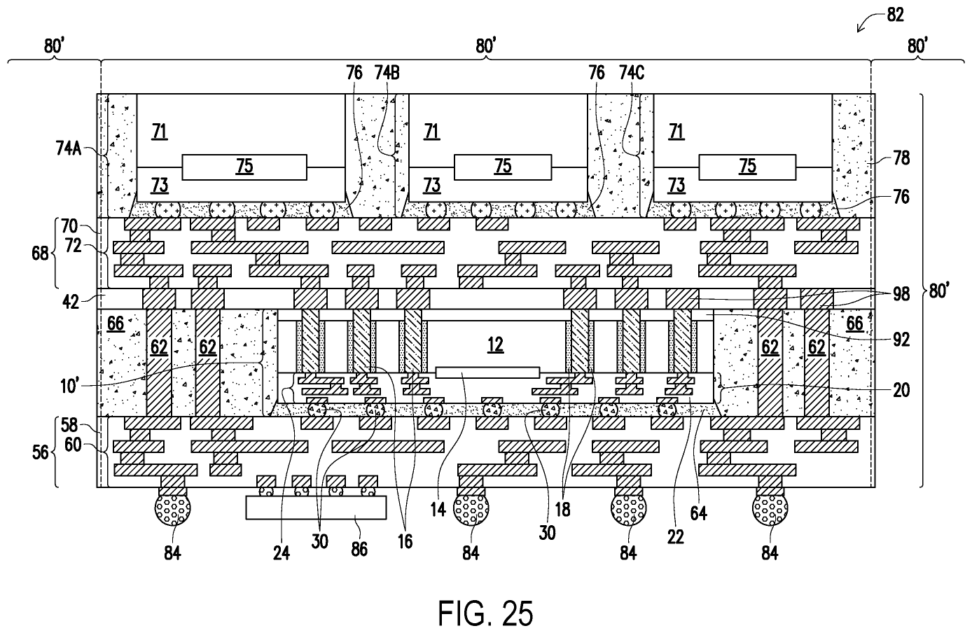

FIGS. 24 and 25 illustrate cross-sectional views of semiconductor packages in accordance with alternative embodiments of the present disclosure. The embodiments of FIG. 24 are similar to the embodiments of FIGS. 1-17, and the embodiments of FIG. 25 are similar to the embodiments of FIGS. 18-23. However, forming the buffer structures of FIGS. 24 and 25 involve forming metal vias before forming a dielectric layer over the metal vias (e.g., as compared to FIGS. 13-14 and FIGS. 19-20, respectively).

Referring to FIG. 24, in some embodiments, metal vias 96 and dielectric layer 42 may be formed differently than as illustrated and described in connection with FIGS. 13 and 14. For example, the formation of metal vias 96 may comprise depositing a metal seed layer (not specifically illustrated) over a top surface of encapsulant 66, metal posts 62, and dielectric isolation layer 38. The metal seed layer may comprise a titanium layer and a copper layer over the titanium layer, or may be a copper layer. A plating mask such as a photoresist is formed over the metal seed layer and patterned to form openings. A conductive material is then plated into the openings. The conductive material may comprise copper, aluminum, solder, nickel, tungsten, cobalt, palladium, titanium, titanium nitride, tantalum, tantalum nitride, or the like, or combinations thereof. Accordingly, the sidewalls of the metal vias 96 may be substantially vertical and straight within process variation (e.g., different than the slanted sidewalls of metal vias 40). Dielectric layer 42 may then be formed over metal vias 96, followed by a planarization process to level the top surface of dielectric layer 42 with the top ends of metal vias 96. In some embodiments, after the planarization, metal vias 96 may remain covered by dielectric layer 42. Note that dielectric layer 42 may be an organic material such as the materials listed in connection with FIG. 13.

Optionally, when plated, metal vias 96 may include non-solder lower portions (e.g., formed of the precedingly discussed non-solder materials) and solder upper portions over the respective non-solder lower portions. The solder upper portions are softer than the non-solder lower portions, and are more suitable for probing. Alternatively, the plated material is a homogeneous material such as those listed above, including copper, a copper alloy, tungsten, or the like.

Similarly as with metal vias 40A, the weight of the conductive materials of metal vias 96A cause directly underlying portions of dielectric isolation layer 38 to compress. As a result, metal vias 96A may physically contact sidewalls of top portions of TSVs 16. For example, dielectric isolation layer 38 may compress an amount ranging from 0.3 μm to 0.5 μm, such as being about 0.5 μm. Heights of metal vias 96A may be equal to the thickness of dielectric layer 42 plus the compression depth (e.g., about 0.5 μm).

It should also be noted that the weight of the conductive materials of metal vias 96B may be substantially supported by directly underlying portions of encapsulant 62. As a result, heights of metal vias 96B may be equal to the thickness of dielectric layer 42. For example, heights of metal vias 96A may be greater than heights of metal vias 96B.

Referring to FIG. 25, in some embodiments, metal vias 98 and dielectric layer 92 may be formed differently than as illustrated and described in connection with FIGS. 19 and 20. However, the buffer structure may be formed similarly as described in connection with FIG. 24, except that dielectric layer 92 may be an inorganic material such as the materials listed in connection with FIG. 19. In particular, the buffer structure (e.g., metal vias 98 and dielectric layer 92) may be formed similarly as the buffer structure (e.g., metal vias 96 and dielectric layer 42) described in connection with FIG. 24. As such, metal vias 96A are formed directly over TSVs 16, and metal vias 96B are formed directly over metal posts 62. However, similarly as with FIG. 20, the weight of the conductive materials of metal vias 98 may be substantially supported by directly underlying portions of dielectric isolation layer 92 and encapsulant 62. As a result, heights of metal vias 94 may be equal to the thickness of dielectric layer 42.

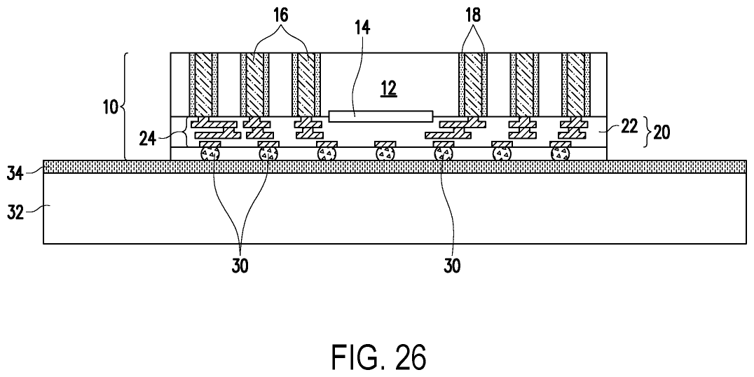

FIGS. 26 through 34 illustrate cross-sectional views of intermediate stages in the formation of a semiconductor package, in accordance with additional embodiments of the present disclosure. These embodiments are similar to the various embodiments shown in FIGS. 1 through 25, except, e.g., the device wafer 10 is processed to form metal vias 14A (e.g., similar to metal vias 40A or metal vias 94) before singulating and bonding device die 10′ to redistribution structure 56. The resulting metal vias 14A formed over TSVs 16 may have similar shapes as metal vias 40A (see, e.g., FIGS. 13-14) or similar shapes as metal vias 94 (see, e.g., FIGS. 19-20). Unless otherwise specified, the materials, the structures, and the formation processes of the components in these embodiments are essentially the same as (e.g., analogous to) the like components described above in connection with the other embodiments. The details regarding the materials, the structures, and the formation processes of the components shown in FIGS. 26 through 36 may thus be found in the discussion of the preceding embodiments.

FIG. 26 illustrates device wafer 10 after a backside thinning process is performed on the backside of device wafer 10 of FIG. 2, wherein semiconductor substrate 12 is thinned. The backside thinning process may be performed through a CMP process or a mechanical grinding process. In some embodiments, following the backside thinning process, TSVs 16 are exposed.

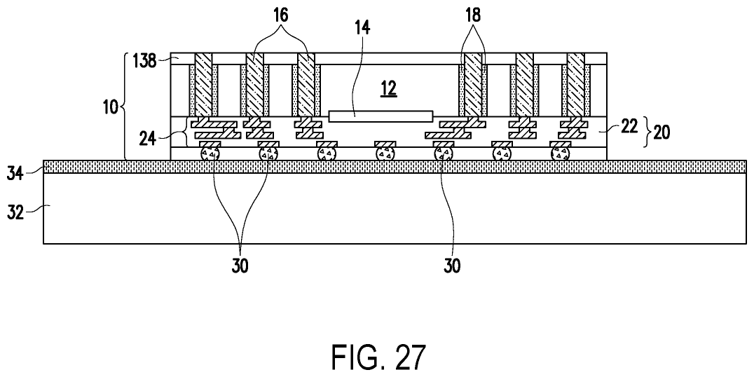

FIG. 27 illustrates recessing the semiconductor substrate 12 through an etch-back process, filling the recesses with dielectric isolation layer 138, and performing a planarization to remove the portions of dielectric isolation layer 138 higher than the top ends of TSVs 16. For example, recessing the semiconductor substrate 12 may be performed similarly as described above in connection with FIG. 10, albeit without first forming a photoresist. As such, the recessing may be performed with greater efficiency and increased yield. In addition, dielectric isolation layer 138 may be deposited similarly as described above in connection with FIG. 11. In some embodiments, dielectric isolation layer 138 may comprise an organic dielectric material such as PBO, polyimide, BCB, or the like (see FIGS. 11 and 12). Alternatively, dielectric isolation layer 138 may comprise an inorganic material such as silicon oxide, silicon nitride, silicon carbide, silicon oxynitride, silicon oxycarbide, silicon oxycarbonitride, or the like, or combinations thereof (see FIG. 18). Further, the planarization process may be performed to level dielectric isolation layer 138 with TSVs 16, similarly as described above in connection with FIGS. 12 and 18.

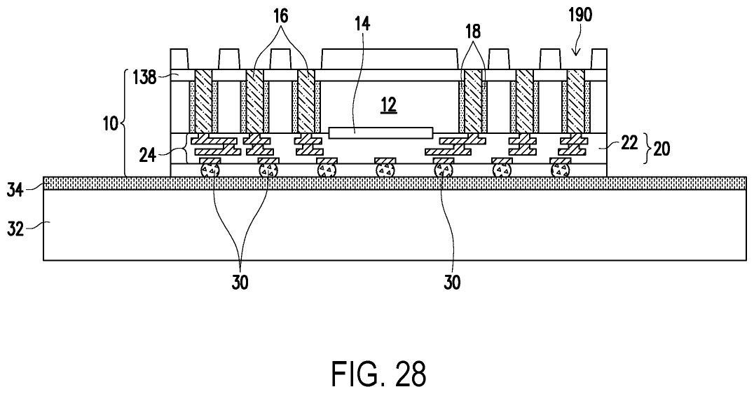

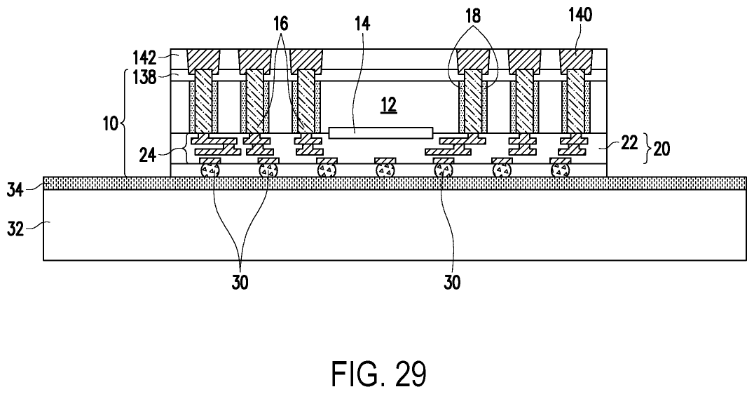

FIGS. 28 and 29 illustrate forming a buffer structure comprising metal vias 140 embedded in dielectric layer 142. For example, metal vias 140 may be formed over device die 10′ through a damascene process, in accordance with various embodiments. For example, formation and patterning of dielectric layer 142 to form openings 90 may be performed similarly as described above in connection with FIGS. 13 and 19. In addition, formation of metal vias 140 may be performed similarly as described above in connection with FIGS. 14 and 20.

In addition, metal vias 140 are formed in openings 190 over both TSVs 16, similarly as described above in connection with FIGS. 14 and 20. As illustrated, the weight and density of the conductive materials of metal vias 140 may outweigh and compress directly underlying portions of dielectric isolation layer 138, such as in embodiments in which dielectric isolation layer 138 comprises an organic dielectric material. As a result, heights of metal vias 140A may be greater than the thickness of dielectric layer 142. In other embodiments, the weight of the conductive materials of metal vias 140A may be substantially supported by directly underlying portions of dielectric isolation layer 138, such as in embodiments in which dielectric isolation layer 138 comprises an inorganic dielectric material. As a result, heights of metal vias 140A may be substantially equal to the thickness of dielectric layer 142.

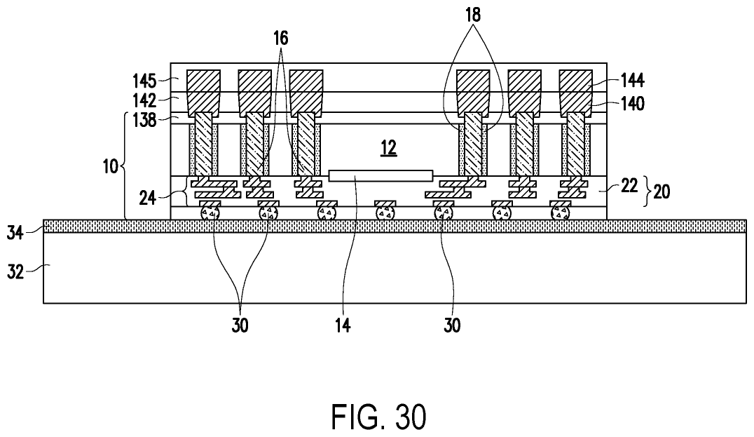

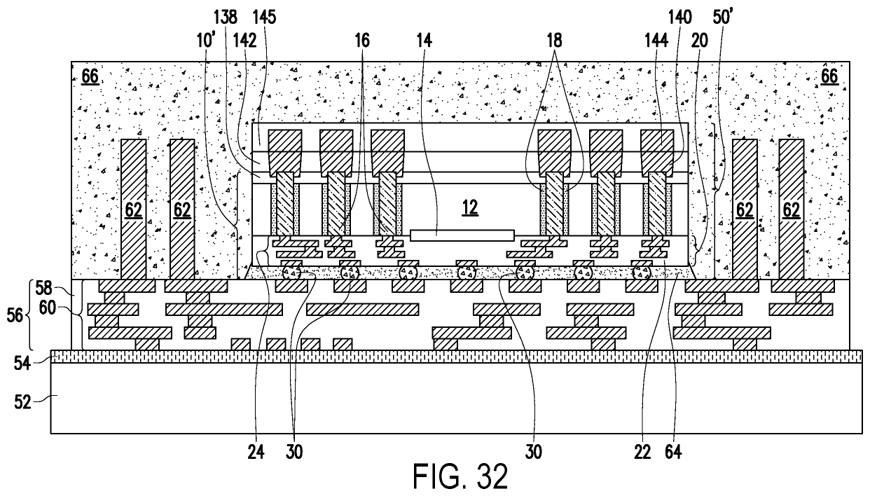

FIG. 30 illustrates forming metal bumps 144 and a dielectric layer 145 over the buffer structure. The metal bumps 144 may provide back side electric connection of device die 10′ when subsequently incorporated into a semiconductor package (see FIGS. 32-34). Metal bumps 144 may be formed by any suitable method, such as similarly as described above in connection with electrical connectors 30 (see FIG. 1). In some embodiments, a seed layer (not specifically illustrated) may be formed over the structure, a sacrificial material may be deposited over the seed layer and patterned to form openings, a conductive material may be formed in the openings, and the sacrificial material may be removed. For example, the conductive material may comprise copper, nickel, aluminum, gold, multi-layers thereof, alloys thereof, or the like. Dielectric layer 145 may then be deposited around and over metal bumps 144. As illustrated, upper surfaces of metal bumps 144 may be covered by dielectric layer 145. In other embodiments (not specifically illustrated), metal bumps 144 and dielectric layer 145 may be formed directly on metal vias 140 and dielectric isolation layer 138 without first forming the buffer structure.

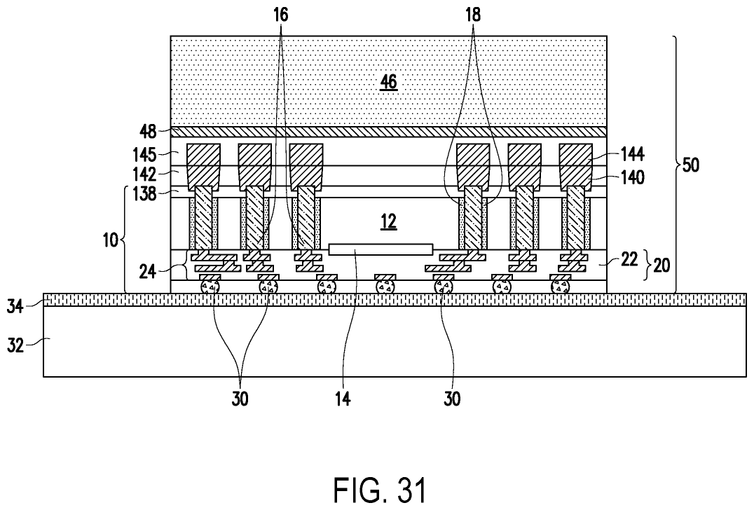

FIG. 31 illustrates the attachment of sacrificial carrier 46 to wafer 10. The attachment may be performed using adhesion film 48, similarly as described above in connection with FIG. 4. Sacrificial carrier 46 may be formed of or comprise a silicon wafer, a glass wafer, or the like and provide mechanical support. Sacrificial carrier 46 may also be an inorganic or an organic carrier. Throughout the description, the structure including wafer 10 and the sacrificial carrier 46 may be collectively referred to as composite wafer 50.

FIG. 32 illustrates, after attaching sacrificial carrier 46, carrier 32 and release film 34 are removed, composite wafer 50 is singulated to form composite dies 50′ (e.g., device dies 10′ and sacrificial dies 46′), one or more composite dies 50′ are attached to redistribution structure 56, sacrificial carrier 46 is removed, and encapsulant 66 is formed over and around composite die 50′ and metal posts 62. For example, these processes may be performed similarly as described above in connection with FIGS. 5-8.

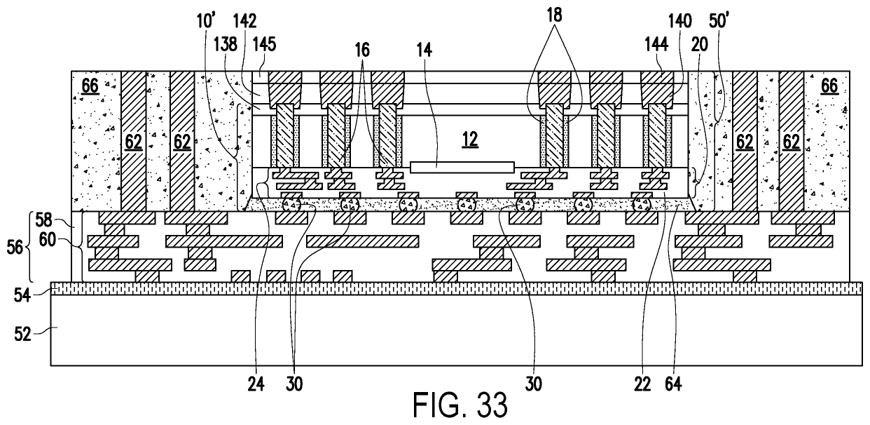

FIG. 33 illustrates a planarization process such as a CMP process or a mechanical grinding process is performed to thin encapsulant 66 to expose and become level with metal posts 62 and metal bumps 144, similarly as described above in connection with FIG. 9. As discussed above, metal posts 62 may also be referred to as through-vias 62. In some embodiments (not specifically illustrated), the planarization process may be used to remove sacrificial die 46′, similarly as described above in connection with FIG. 9. As illustrated, after removing portions of dielectric layer 145 over metal bumps 144, the planarization process may also thin metal bumps 144. As a result of the planarization process, metal bumps 144, dielectric layer 145, encapsulant 66, and metal posts 62 may be level within process variations.

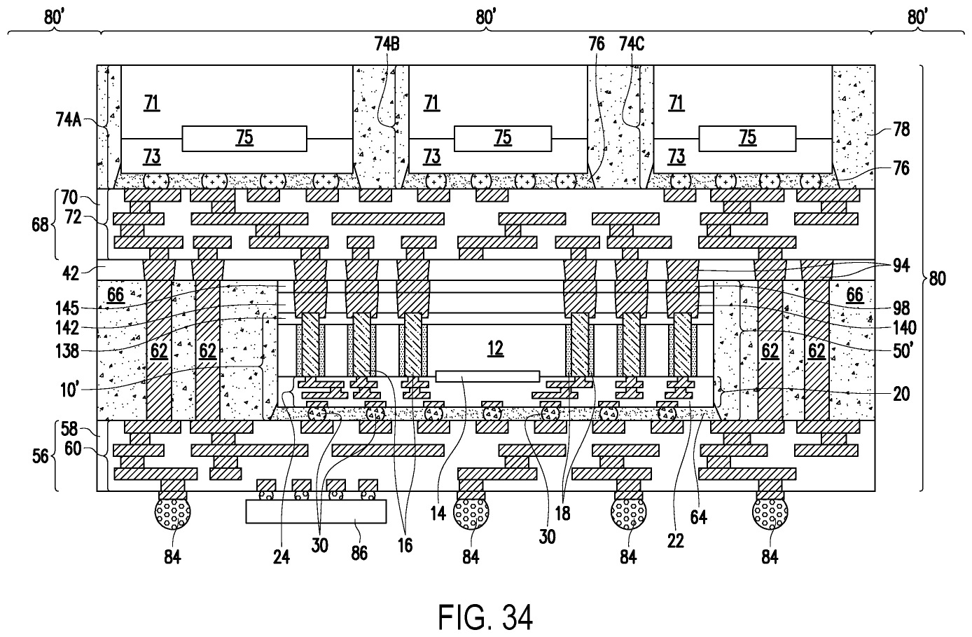

FIG. 34 illustrates forming a buffer structure comprising metal vias 94 embedded in dielectric layer 42, similarly as described above in connection with FIGS. 19 and 20. As noted above, in some embodiments (not specifically illustrated), this buffer structure is formed instead of the buffer structure discussed in connection with FIGS. 28 and 29. As illustrated, metal vias 94 are formed in electrical connection with metal posts 62 and metal bumps 98. In addition, redistribution structure 68 is formed over and electrically connected to metal vias 94, package components 74 (e.g., package components 74A/B/C) are attached to redistribution structure 68 and encapsulated in encapsulant 78, similarly as described above in connection with FIGS. 16 and 22. Further, carrier 52 may be removed before forming electrical connectors 84 on and attaching Independent Passive Device (IPD) dies 86 to redistribution structure 56, similarly as described above in connection with FIGS. 17 and 23.

In above-illustrated embodiments, some processes and features are discussed in accordance with some embodiments of the present disclosure to form a three-dimensional (3D) semiconductor package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. For example, fabrication and packaging processes are improved by exposing TSVs 16 of device dies 10′ at the wafer level (e.g., wafer 1o) by using a backside thinning process that is specific to the surface of wafer 10. In addition, quality and yield of device dies 10′ are improved by reducing the amount of time that carrier 32 is adhered to wafer 10 by release film 34 (e.g., glue). This is achieved by forming buffer structure over device dies 10′ after attachment of device dies 10′ to redistribution structure 56.

In an embodiment, a method includes: forming a first redistribution structure over a substrate; forming a metal post over the first redistribution structure; attaching a first device die to the first redistribution structure, the first device die comprising a through via embedded in a semiconductor substrate; encapsulating the metal post and the first device die in an encapsulant, a first top surface of the encapsulant being level with a second top surface of the semiconductor substrate; recessing the second top surface to expose the through via; forming a dielectric isolation layer around the through via; forming a dielectric layer over the dielectric isolation layer; etching the dielectric layer to form a first opening and a second opening in the dielectric layer; forming a first metal via in the first opening and a second metal via in the second opening; and forming a second redistribution structure over the dielectric layer, the second redistribution structure being electrically connected to the first metal via and the second metal via. In another embodiment, forming the second metal via comprises compressing a portion of the dielectric isolation layer directly below material of the second metal via. In another embodiment, a height of the second metal via is greater than a height of the first metal via. In another embodiment, the metal post is electrically interposed between the first redistribution structure and the second redistribution structure. In another embodiment, a front side of the first device die is attached to and electrically coupled to the first redistribution structure. In another embodiment, the through via is electrically interposed between the first redistribution structure and the second redistribution structure. In another embodiment, the dielectric isolation layer comprises an organic material. In another embodiment, the method further includes forming the device die, wherein forming the device die comprises: forming the through via partially through the semiconductor substrate; forming an interconnect structure over the through via; attaching the interconnect structure to a first carrier; thinning at least a portion of the semiconductor substrate; attaching a second carrier to the semiconductor substrate; and removing the first carrier. In another embodiment, the method further includes: attaching a second device die and a third device die to the second redistribution structure; removing the substrate; and forming an electrical connector along the first redistribution structure.

In an embodiment, a method includes: forming a device die, forming the device die comprising: forming an interconnect structure over a front side of a semiconductor substrate, a through via extending partially through the semiconductor substrate; forming electrical connectors over the interconnect structure; attaching a first carrier to the electrical connectors using a glue; thinning a back side of the semiconductor substrate; attaching a second carrier to the back side of the semiconductor substrate; removing the first carrier; and singulating the semiconductor substrate; forming a first redistribution structure over a first carrier substrate; forming a metal post over the first redistribution structure; attaching the electrical connectors of the device die to the first redistribution structure; encapsulating the metal post and the device die in an encapsulant; recessing the back side of the semiconductor substrate below a top end of the through via; depositing a dielectric isolation layer around the top end of the through via; and forming a buffer structure over the dielectric isolation layer, the buffer structure comprising a first metal via and a second metal via embedded in a dielectric layer. In another embodiment, the first metal via and the second metal via are coplanar with an upper surface of the dielectric layer, and wherein the first metal via extends beyond a lower surface of the dielectric layer and into the dielectric isolation layer. In another embodiment, the second metal via is coplanar with the lower surface of the dielectric layer. In another embodiment, forming the buffer structure comprises: depositing the dielectric layer over the encapsulant and the dielectric isolation layer; forming a first opening and a second opening in the dielectric layer, the first opening exposing the through via and a portion of the dielectric isolation layer, a top surface of the through via being coplanar with a top surface of the portion of the dielectric isolation layer, the second opening exposing the metal post; and depositing a conductive material in the first opening and the second opening. In another embodiment, depositing the conductive material in the first opening comprises compressing the top surface of the portion of the dielectric isolation layer to be below the top surface of the through via. In another embodiment, the method further includes: forming a second redistribution structure over the buffer structure; attaching a memory die and a logic die over the second redistribution structure; and forming external connectors along the first redistribution structure.

In an embodiment, a semiconductor device includes: a device die attached to a first redistribution structure, the device die comprising: electrical connectors coupled to the first redistribution structure; an interconnect structure over the electrical connectors; a semiconductor substrate over the interconnect structure; and a through via extending through the semiconductor substrate; a first dielectric layer over the device die; an encapsulant around lateral edges of the device die and the first dielectric layer, the encapsulant being level with the first dielectric layer; a second dielectric layer over the encapsulant and the device die; a first metal via embedded in the second dielectric layer and connected to the through via, a portion of the first metal via extending into the first dielectric layer; a second metal via embedded in the second dielectric layer and laterally displaced from the device die; and a second redistribution structure over the second dielectric layer and connected to the first metal via and the second metal via. In another embodiment, the first metal via is in physical contact with a top surface and a first sidewall of the through via. In another embodiment, the first metal via is in physical contact with a second sidewall of the through via, and wherein the second sidewall is opposite of the first sidewall. In another embodiment, the first dielectric layer comprises an organic material. In another embodiment, the semiconductor device further includes a metal post over the first redistribution structure and extending through the encapsulant, wherein the second metal via is embedded in the second dielectric layer and connected to the metal post, and wherein a height of the first metal via is greater than a height of the second metal via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first redistribution structure over a substrate;
forming a metal post over the first redistribution structure;
attaching a first device die to the first redistribution structure, the first device die comprising a through via embedded in a semiconductor substrate;
encapsulating the metal post and the first device die in an encapsulant, a first top surface of the encapsulant being level with a second top surface of the semiconductor substrate;
recessing the second top surface to expose the through via;
forming a dielectric isolation layer around the through via;
forming a dielectric layer over the dielectric isolation layer;
etching the dielectric layer to form a first opening and a second opening in the dielectric layer;
forming a first metal via in the first opening and a second metal via in the second opening; and
forming a second redistribution structure over the dielectric layer, the second redistribution structure being electrically connected to the first metal via and the second metal via.

2. The method of claim 1, wherein forming the second metal via comprises compressing a portion of the dielectric isolation layer directly below material of the second metal via.

3. The method of claim 2, wherein a height of the second metal via is greater than a height of the first metal via.

4. The method of claim 1, wherein the metal post is electrically interposed between the first redistribution structure and the second redistribution structure.

5. The method of claim 1, wherein a front side of the first device die is attached to and electrically coupled to the first redistribution structure.

6. The method of claim 5, wherein the through via is electrically interposed between the first redistribution structure and the second redistribution structure.

7. The method of claim 1, wherein the dielectric isolation layer comprises an organic material.

8. The method of claim 1, further comprising forming the device die, wherein forming the device die comprises:
forming the through via partially through the semiconductor substrate;
forming an interconnect structure over the through via;
attaching the interconnect structure to a first carrier;
thinning at least a portion of the semiconductor substrate;
attaching a second carrier to the semiconductor substrate; and
removing the first carrier.

9. The method of claim 8, further comprising:
attaching a second device die and a third device die to the second redistribution structure;
removing the substrate; and
forming an electrical connector along the first redistribution structure.

10. A method comprising:
forming a device die, forming the device die comprising:
forming an interconnect structure over a front side of a semiconductor substrate, a through via extending partially through the semiconductor substrate;
forming electrical connectors over the interconnect structure;
attaching a first carrier to the electrical connectors using a glue;
thinning a back side of the semiconductor substrate;
attaching a second carrier to the back side of the semiconductor substrate;
removing the first carrier; and
singulating the semiconductor substrate;
forming a first redistribution structure over a first carrier substrate;
forming a metal post over the first redistribution structure;
attaching the electrical connectors of the device die to the first redistribution structure;
encapsulating the metal post and the device die in an encapsulant;
recessing the back side of the semiconductor substrate below a top end of the through via;
depositing a dielectric isolation layer around the top end of the through via; and
forming a buffer structure over the dielectric isolation layer, the buffer structure comprising a first metal via and a second metal via embedded in a dielectric layer.

11. The method of claim 10, wherein the first metal via and the second metal via are coplanar with an upper surface of the dielectric layer, and wherein the first metal via extends beyond a lower surface of the dielectric layer and into the dielectric isolation layer.

12. The method of claim 11, wherein the second metal via is coplanar with the lower surface of the dielectric layer.

13. The method of claim 10, wherein forming the buffer structure comprises:
depositing the dielectric layer over the encapsulant and the dielectric isolation layer;
forming a first opening and a second opening in the dielectric layer, the first opening exposing the through via and a portion of the dielectric isolation layer, a top surface of the through via being coplanar with a top surface of the portion of the dielectric isolation layer, the second opening exposing the metal post; and
depositing a conductive material in the first opening and the second opening.

14. The method of claim 13, wherein depositing the conductive material in the first opening comprises compressing the top surface of the portion of the dielectric isolation layer to be below the top surface of the through via.

15. The method of claim 10, further comprising:
forming a second redistribution structure over the buffer structure;
attaching a memory die and a logic die over the second redistribution structure; and
forming external connectors along the first redistribution structure.

16. A semiconductor device comprising:
a device die attached to a first redistribution structure, the device die comprising:
electrical connectors coupled to the first redistribution structure;
an interconnect structure over the electrical connectors;
a semiconductor substrate over the interconnect structure; and
a through via extending through the semiconductor substrate;
a first dielectric layer over the device die;
an encapsulant around lateral edges of the device die and the first dielectric layer, the encapsulant being level with the first dielectric layer;
a second dielectric layer over the encapsulant and the device die;
a first metal via embedded in the second dielectric layer and connected to the through via, a portion of the first metal via extending into the first dielectric layer;
a second metal via embedded in the second dielectric layer and laterally displaced from the device die; and
a second redistribution structure over the second dielectric layer and connected to the first metal via and the second metal via.

17. The semiconductor device of claim 16, wherein the first metal via is in physical contact with a top surface and a first sidewall of the through via.

18. The semiconductor device of claim 17, wherein the first metal via is in physical contact with a second sidewall of the through via, and wherein the second sidewall is opposite of the first sidewall.

19. The semiconductor device of claim 16, wherein the first dielectric layer comprises an organic material.

20. The semiconductor device of claim 16, further comprising a metal post over the first redistribution structure and extending through the encapsulant, wherein the second metal via is embedded in the second dielectric layer and connected to the metal post, and wherein a height of the first metal via is greater than a height of the second metal via.
